(19) United States
(12) Patent Application Publication
(10) Pub. No.: US 2026/0150363 A1
(43) Pub. Date: May 28, 2026

(54) SIDEWALL SPACER TRIMMING

(71) Applicant: Taiwan Semiconductor Manufacturing Company, Ltd., Hsinchu (TW)

(72) Inventors: Shao-Hua Hsu, Taitung City (TW); Yuan-Cheng Hu, Taichung City (TW); Chia-I Lin, Taipei City (TW); Kai-Min Chien, New Taipei City (TW); Yu-Jiun Peng, Hsinchu (TW)

(73) Assignee: Taiwan Semiconductor Manufacturing Company, Ltd., Hsinchu (TW)

(21) Appl. No.: 18/956,632

(22) Filed: Nov. 22, 2024

(51) Int. Cl. H01L 29/66; H01L 21/8234; H01L 27/088; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 84/0128; H10D 84/038; H10D 84/83

(57) ABSTRACT

Provided are semiconductor structures and methods for fabricating semiconductor structures. A method includes forming a stack of semiconductor nanosheets over a substrate; forming a sacrificial gate structure over the stack of semiconductor nanosheets; forming a liner adjacent to the sacrificial gate structure; forming a dielectric layer adjacent to the liner; removing the sacrificial gate structure to form a gate cavity; performing an oxidation process to oxidize a portion of the liner adjacent to the gate cavity; and removing the portion of the liner adjacent to the gate cavity.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far the demand has been met in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, to reduce OFF-state current, and to reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFET devices and GAA devices are compatible with conventional complementary metal-oxide-semiconductor (CMOS) processes. Further, the three-dimensional structure of such devices allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIG. 2 is a flow chart illustrating a method, in accordance with some embodiments.

FIGS. 3-14 are cross-sectional views of the semiconductor device during successive stages of fabrication according to the method of FIG. 2, in accordance with some embodiments.

FIG. 15 is a flow chart illustrating a sidewall trimming process, in accordance with some embodiments.

FIGS. 16-24 are cross-sectional views of the semiconductor device during successive stages of fabrication according to the process of FIG. 15, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, at least 75 wt. % of the identified material, or at least 90 wt. % of the identified material, or substantially 100 wt. % of the identified material; and a layer that is a “material” includes at least 50 wt. % of the identified material, for example at least 60 wt. % of the identified material, at least 75 wt. % of the identified material, or at least 90 wt. % of the identified material, or substantially 100 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. %, or at least 95 wt. %, or substantially 100 wt. %, titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

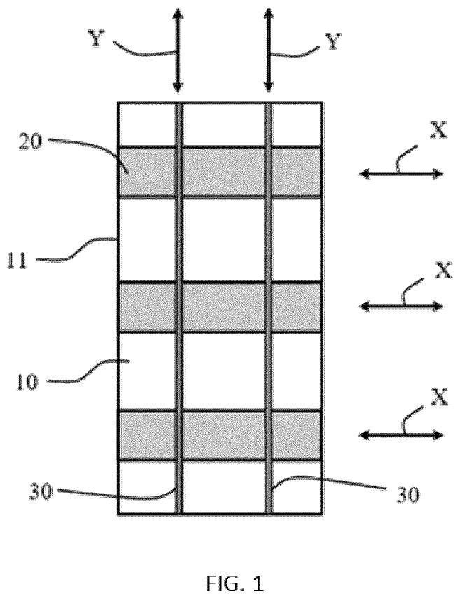

FIG. 1 illustrates a unit cell 11, i.e., a portion of the semiconductor substrate 10 in a semiconductor device 100. As shown, parallel active regions 20 are spaced apart from one another and extend in an X-direction. Further, parallel gate lines 30 are spaced apart from one another and extend in a Y-direction perpendicular to the X-direction. Exemplary gate lines 30 are formed from conductive material such as metal and form gate structures for the device 100.

The semiconductor device 100 may be a multi-gate device 100. In various embodiments, the multi-gate device 100 may include a FinFET device, a GAA transistor, or other type of multi-gate device. The multi-gate device 100 is formed over a substrate 10.

The multi-gate devices 100 may include a P-type metal-oxide-semiconductor device 100 or an N-type metal-oxide-semiconductor multi-gate device 100. Specific examples may be presented and referred to herein as FinFET devices 100, on account of their fin-like structure. Also presented herein are embodiments of a type of multi-gate transistor referred to as a gate-all-around (GAA) device 100. A GAA device 100 includes any device that has its gate structure, or portion thereof, formed on four sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, the terms “nanosheet” or “nanosheet channel” are intended to include nanowire channel and bar-shaped channel configurations.

In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

Presented herein are embodiments of devices that may have one or more channel regions (e.g., nanosheets) associated with a gate structure. For example, a stack of vertically spaced nanosheet channels may be provided. However, one of ordinary skill would recognize that the teaching can apply to a single channel (e.g., single nanosheet) or any number of channels. One of ordinary skill may recognize other examples of semiconductor devices that may benefit from aspects of the present disclosure.

It has been found that metal gate extrusion may inhibit performance of devices with nanosheet channel regions. The metal gate extrusion may create an electrical path between the gate and a source/drain feature. As used herein, “source/drain region(s)” or “source/drain feature(s)” may refer to a source or a drain, individually or collectively dependent upon the context. The electrical path between the gate and source/drain feature leads to an unwanted leakage current.

Metal gate extrusion may occur when the metal gate is formed with a step-like profile. Specifically, an upper portion of the metal gate has a larger lateral width or critical dimension than a lower portion of the metal gate. Thus, there is a shorter lateral distance from the upper portion of the metal gate and the adjacent region over a source/drain feature, such as where a contact to the source/drain feature is formed. The shorter lateral distance may potentially lead to unwanted metal gate extrusion and a leakage current.

In order to improve device RO % boosting, low-K film may be used as a sidewall spacer formed on the sacrificial gate. Harder materials, which are more resistant to oxide etching processes, may be used as a sacrificial layer during sidewall spacer trim processes. However, it has been found that the oxide etching processes result in a top-to-bottom oxidation rate loading. Specifically, more of the material to be removed is converted to oxide at higher locations, while less of the material to be removes is converted to oxide at lower locations. This tendency is more significant for a low-k sidewall spacer because the oxidation rate of the low-K sidewall spacer is much faster than the oxidation rate of the harder sacrificial layer. As a result, oxide etching processes used to remove portions of the low-K sidewall spacer have been found to result in a remaining portion of the low-K sidewall spacer having a step-like profile and a non-uniform thickness. Specifically, the thickness of the oxide-etched low-K sidewall spacer is largest at the bottom of the sidewall and includes a step from the thick lower portion to a thinner middle portion. This step structure creates a higher likelihood of a metal gate extrusion defect and degrades RO %.

Certain embodiments herein prevent formation of a sidewall spacer having a stepped profile. For example, certain embodiments include performing an oxide etching process or sidewall trim process at a high pressure to allow for more uniform reactant distribution during oxidation. More uniform reactant distribution reduces top-to-bottom oxidation rate loading. In other words a uniform lateral thickness of the material to be removed is converted to oxide along the sidewall, at higher and lower locations. As a result, the sidewall liner is formed with a more linear profile, such as a more vertical profile, and a more uniform lateral thickness. Thus, when the metal gate is formed in contact with the sidewall liner, the metal gate has a more liner profile, i.e., a more vertical profile. More specifically, the metal gate is formed without any lateral step from a thinner portion to a thicker portion.

Certain embodiments relate to a method for fabricating a nanosheet FET with an improved dummy poly sidewall spacer trim process. In particular, certain embodiments relate to the formation of a dummy polysilicon trench structure with less top-to-bottom critical dimension loading and more uniform spacer thickness. These features may be beneficial for reducing gate to source/drain leakage and boosting RO % device performance.

In certain embodiments, a gate cavity is formed by removing a sacrificial or dummy polysilicon gate structure, and then a sidewall spacer trim process is performed. The sidewall spacer trim process is performed with an increased oxidation treatment pressure followed by oxide removal etch process.

The high pressure oxidation process provides a more uniform reactant top-to-bottom distribution, forming a uniform oxidation layer top-to-bottom from the low-K material. Thus, the sidewall spacer trim process achieves a more vertical profile with uniform spacer thickness. Then, the metal gate formed on the sidewall spacer also has a vertical profile, lowering the risk of metal gate extrusion by increasing the metal gate (MG) to source/drain contact (MD) spacing, and reducing defect concerns. In certain embodiments, process avoids forming the metal gate with a step-like shape, which can be beneficial to defect and electrical performance.

Thus, embodiments herein reduce metal gate extrusion risk, reduce effective capacitance, and boost RO % performance.

As device scale shrinks in nanosheet FET technology, the sidewall spacer trim process may be a key for metal gate profile modulation with less defects in order to boost device performance and yield.

Embodiments of the present disclosure offer advantages over the existing art, though it is understood that other embodiments may offer different advantages, not all advantages are necessarily discussed herein, and no particular advantage is required for all embodiments.

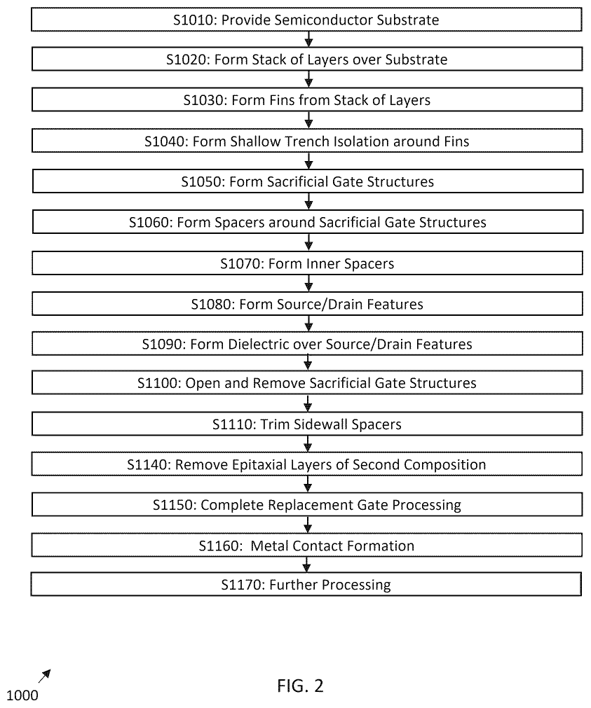

Referring to FIG. 2, illustrated therein is a method 1000 of fabrication of a semiconductor device 200 (such as a multi-gate device 100), in accordance with various embodiments. Method 1000 is discussed below with reference to a GAA device 200 having a channel region that may be referred to as a nanosheet or nanosheet channel and which may include various geometries (e.g., cylindrical, bar-shaped) and dimensions. However, it will be understood that aspects of method 1000 may be equally applied to other types of multi-gate devices without departing from the scope of the present disclosure. In some embodiments, method 1000 may be used to fabricate the multi-gate device 100, described above with reference to FIG. 1. Thus, one or more aspects discussed above with reference to the multi-gate device 100 may also apply to method 1000. It is understood that method 1000 includes steps having features of a complementary metal-oxide-semiconductor (CMOS) technology process flow and thus, are only described briefly herein. Also, additional steps may be performed before, after, and/or during method 1000.

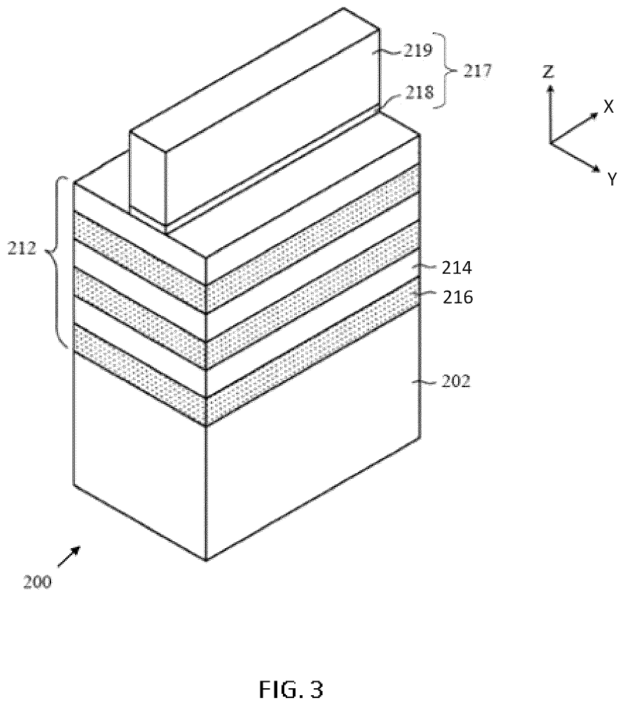

Method 1000 is described below with reference to FIGS. 3-14, which provide perspective views of the multi-gate device 200 or cross-sectional views of the multi-gate device 200 along a plane substantially parallel to a plane defined by the Y and Z axes in FIG. 1, as described, illustrating various stages of fabrication according to method 1000.

Further, the semiconductor device 200 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the concepts of the present disclosure. In some embodiments, the semiconductor device 200includes a plurality of semiconductor devices (e.g., transistors), including PFETs, NFETs, etc., which may be interconnected. Moreover, it is noted that the process steps of method 1000, including any descriptions given with reference to the figures are merely exemplary and are not intended to be limiting beyond what is specifically recited in the claims that follow.

At operation S1010, the method 1000 provides a substrate 202, as shown in FIG. 3. In some embodiments, the substrate 202 may be a semiconductor substrate such as a silicon (Si) substrate. The substrate 202 may include various layers, including conductive or insulating layers formed on a semiconductor substrate. The substrate 202 may include various doping configurations depending on design requirements as is known in the art. For example, different doping profiles (e.g., p-well, n-well) may be formed on the substrate 202 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. In the illustrated embodiment, the substrate 202 is made of crystalline Si.

As shown in FIG. 3, at operation S1020, the method 1000 (FIG. 2) forms one or more epitaxial layers over the substrate 202. In some embodiments, an epitaxial stack 212 is formed over the substrate 202. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. In an embodiment, the epitaxial layers 214 are SiGe and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 3, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 200. In some embodiments, the number of epitaxial layers 216 is between two and ten, such as six or seven.

In some embodiments, the epitaxial layer 214 has a thickness ranging from about five nanometers to about fifteen nanometers. The epitaxial layers 214 may be substantially uniform in thickness. In some embodiments, the epitaxial layer 216 has a thickness ranging from about five nanometers to about fifteen nanometers. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 216 include the same material as the substrate 202. In some embodiments, the epitaxially grown layers 214 and 216 include a different material than the substrate 202. As stated above, in at least some examples, the epitaxial layer 214 includes an epitaxially grown Si₁₋ₓGeₓ layer (wherein x is from about 10 to about 55%) and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

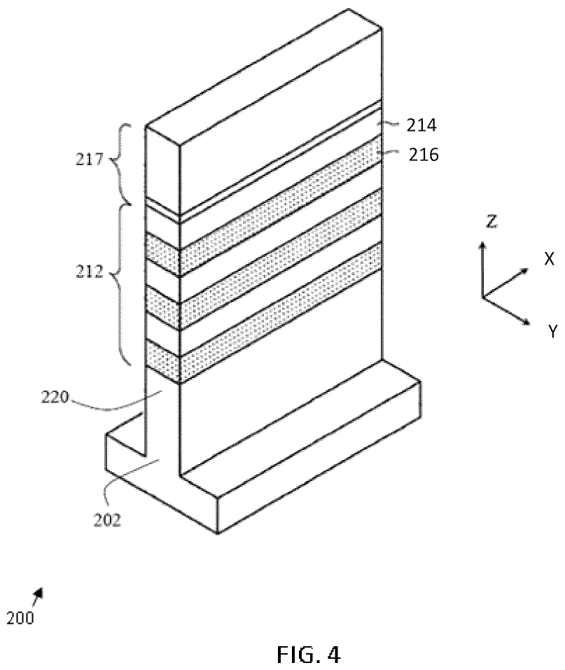

As shown in FIGS. 3-4, at operation S1030, the method 1000 (FIG. 2) patterns the epitaxial stack 212 to form a semiconductor fin 220. In some embodiments, the operation S1030 includes forming a mask layer 217 over the epitaxial stack 212, as shown in FIG. 3. The mask layer 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer 217 is patterned into a mask pattern by using patterning operations including photolithography and etching. Operation S1030 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 216 are thereby patterned into the fin 220. While FIG. 4 illustrates the formation of one fin 220, any suitable number of the fins may be formed. Trenches are etched between adjacent fins 220.

In various embodiments, each fin 220 includes an upper portion of the interleaved epitaxial layers 214 and 216, and a bottom portion that is formed from the etched substrate 202. Each fin 220 protrudes upwardly in the Z-direction from the substrate 202 and extends lengthwise in the Y-direction. Sidewalls of each fin 220 may be straight or inclined (not shown). In FIG. 4, additional fins would be spaced apart along the Y-direction. The fins 220 may have a same width or different widths.

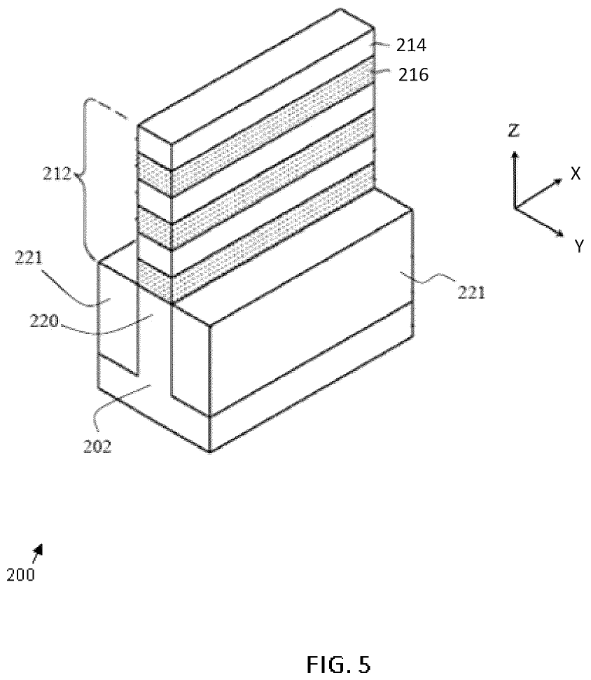

As shown in FIG. 5, at operation S1040, the method 1000 (FIG. 2) forms shallow trench isolation (STI) features (also denoted as STI features) 221 in trenches adjacent to each fin 220 with a dielectric layer. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 221, as shown in FIG. 5. In the illustrated embodiment, the STI features 221 are formed on the substrate 202. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask layer 217 (shown in FIG. 4) may also be removed before, during, and/or after the recessing of the isolation features 221. In some embodiments, the mask layer 217 is removed by the CMP process performed prior to the recessing of the isolation features 221. In some embodiments, the mask layer 217 is removed by an etchant used to recess the isolation features 221.

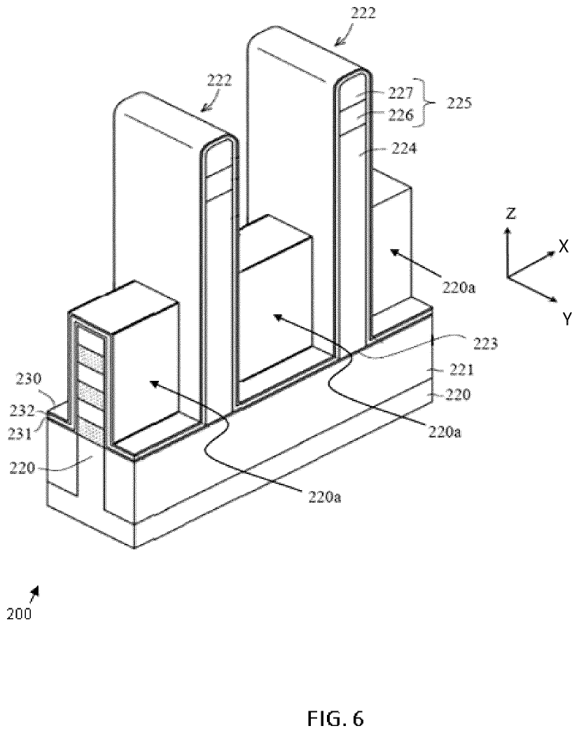

As shown in FIG. 6, at operation S1050, the method 1000 (FIG. 2) forms sacrificial (dummy) gate structures 222. The sacrificial gate structures 222 are formed over portions of the fin 220 which are to be channel regions. The sacrificial gate structures 222 may extend over a number of adjacent fins (not shown). The sacrificial gate structures 222 lie directly over and define the channel regions of the GAA devices to be formed. Each of the sacrificial gate structures 222 includes a sacrificial gate dielectric 223 and a sacrificial gate electrode 224 over the sacrificial gate dielectric 223. As shown, the gate structures 222 extend lengthwise in the Y-direction and are spaced apart in the X-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from about one hundred nanometers to about two hundred nanometers in some embodiments. The sacrificial gate electrode layer 224 includes silicon such as polycrystalline silicon or amorphous silicon. The thickness of the sacrificial gate dielectric layer is in a range from about one nanometer to about five nanometers in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, a patterning operation is performed on the mask layer 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed between and on opposite sides of the sacrificial gate structures 222, thereby defining source/drain (S/D) regions. In this disclosure, a source and a drain are interchangeably used and the structures thereof are substantially the same.

Still referring to FIG. 6, at operation S1060, the method 1000 (FIG. 2) forms spacers 230 on sidewalls of the sacrificial gate structures 222 and sidewalls of the fins 220 by depositing spacer materials, followed by an etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 on a sidewall of the liner layer 231. By way of example, the spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively.

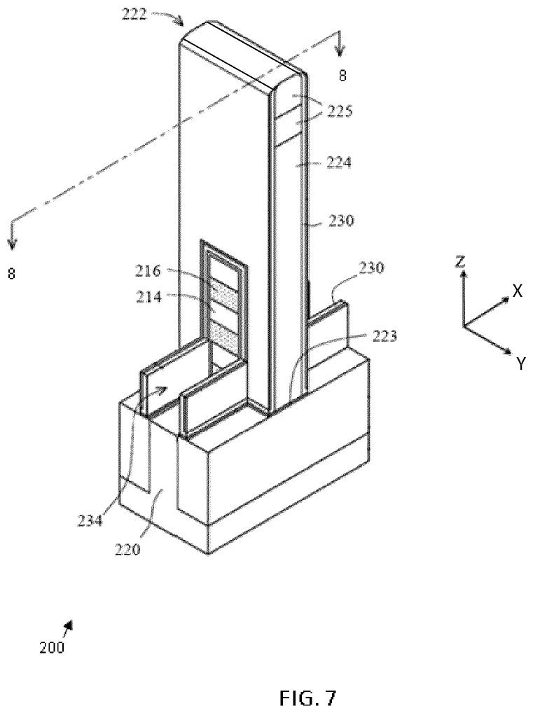

As shown in FIG. 7, the deposition of the liner material layer and the dielectric material layer are followed by, at operation S1070, etching-back (e.g., anisotropically) to expose, and remove, portions 220a of the fins 220 adjacent to and not covered by the sacrificial gate structure 222 (e.g., S/D regions). The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from about five nanometers to about twenty nanometers.

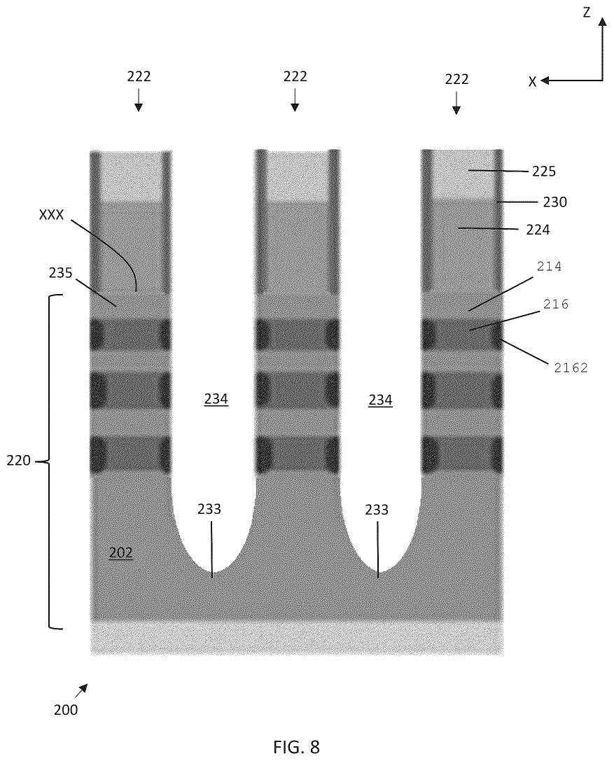

Cross-referencing FIG. 7 with FIG. 8, an X-cut cross-section view, at operation S1070, the method 1000 (FIG. 2) includes forming inner spacers 2162 laterally adjacent to epitaxial layers 216.

For example, operation S1070 may include recessing the portions of the fin 220 not covered by the sacrificial gate structures 222 to form gaps or recesses 234 in the S/D regions. It is noted that FIG. 7 shows only one sacrificial gate structure 222 and the adjacent portion of fin 220 so that etching of the S/D region between the sacrificial gate structures 222 of FIG. 6 may be more clearly viewed. FIG. 8 is a cross sectional-view along line 8-8 in FIG. 7 but illustrates three sacrificial gate structures 222 and a fin 220 lying under the sacrificial gate structures 222.

As shown most clearly in FIG. 8, the stacked epitaxial layers 214 and 216 are etched to a bottom gap surface 233 formed by the fin 220. In many embodiments, the operation S1070 forms the gaps 234 by a suitable etching process, such as a dry etching process, a wet etching process, or a combination thereof. As a result of the etching process, fin segments 235 of the upper portion of the fin 220 are defined and separated from one another by the gaps 234.

Further, operation S1070 may include laterally etching the epitaxial layers 216 of the second composition. In an exemplary embodiment, an SiGe etchback process is performed to laterally recess the layers 216. As a result, pockets are formed laterally adjacent to the layers 216 and vertically adjacent to the layers 214. Operation S1070 includes forming inner spacers 2162 in the pockets. In exemplary embodiments, the inner spacers 2162 may be formed from silicon oxides, silicon nitrides, silicon carbides, silicon carbide nitride, silicon oxide carbide, silicon carbide oxynitride, and/or other suitable dielectric materials. The inner spacers 2162 may be formed by ALD or any other suitable method. As shown, after deposited the material forming inner spacers 2162, the material may be trimmed from the sidewalls of epitaxial layers 214.

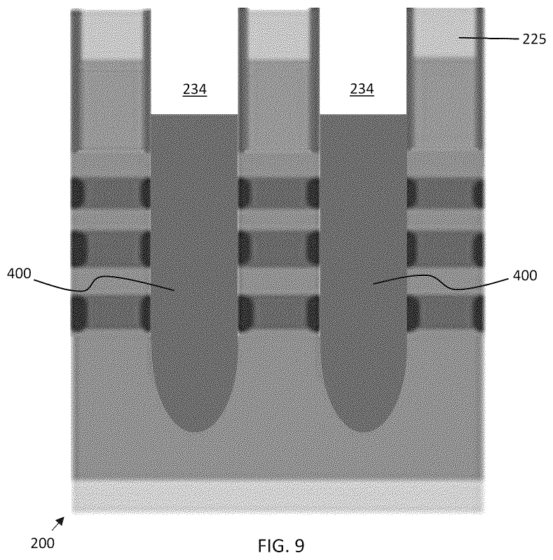

The method may continue, at operation S1080, with forming source/drain features 400, as shown in FIG. 9. FIG. 9 is an X-cut cross-sectional view. In exemplary embodiments, the source/drain features 400 are formed by epitaxial growth. For example, operation S1080 may include selectively growing epitaxial material over the isolation layer 300 to form source/drain features 400. In exemplary embodiments, the source/drain features 400 are strained source/drain features 400.

In exemplary embodiments, the source/drain features 400 may include an n-type epitaxial material source/drain features and a p-type epitaxial material source/drain features. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

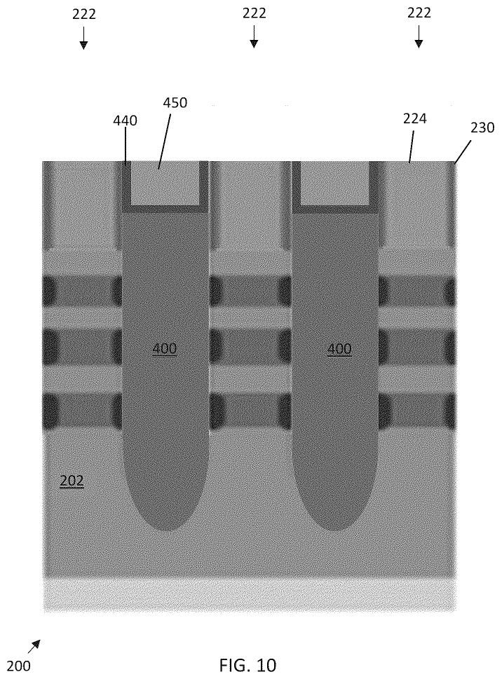

In FIG. 10, method 1000 includes, at operation S1090, capping the source/drain features 400 with dielectric. Specifically, a dielectric liner 440 may be formed over source/drain features 400 and along the sides of the spacers 230. Further, a dielectric 450 may be formed over the liner 440 over the source/drain features 400. Specifically, the gaps 234 are filled with dielectric 450. In exemplary embodiments, the dielectric 450 is a first interlayer dielectric layer (ILD). The dielectric 450 may be silicon oxide or other suitable dielectric material. In certain embodiments, the dielectric liner 440 is a dielectric, such as silicon nitride or another suitable material.

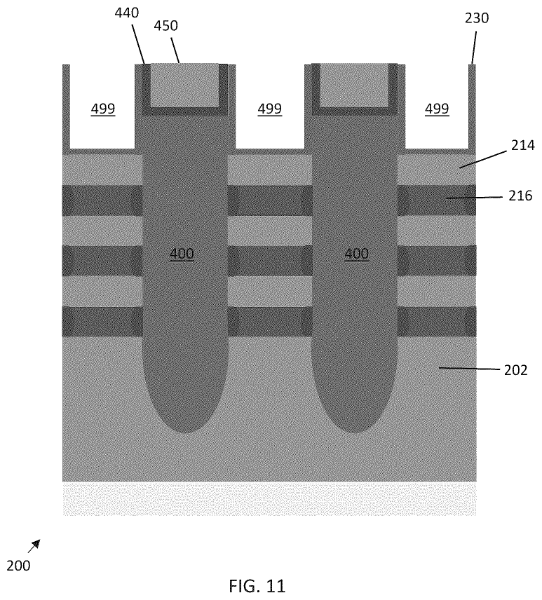

As further shown in FIG. 11, method 1000 includes, at operation S1100, opening and removing the sacrificial gate structures 222. Specifically, a chemical mechanical planarization (CMP) process may be performed to remove the mask layer 225 and to uncover the sacrificial gate electrode 224. Further, the sacrificial gate electrode 224 is removed to form gate cavities 499. As shown, the gate cavities 499 are bounded by the spacers 230 and by the uppermost epitaxial layer 214. FIG. 11 is an X-cut cross-sectional view.

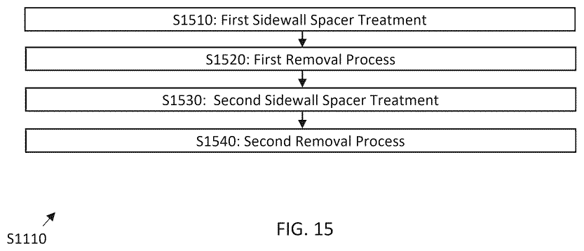

As indicated in FIG. 2 and shown in FIGS. 15-23, method 1000 includes, at operation S1110, trimming the sidewall spacer 230 as described below.

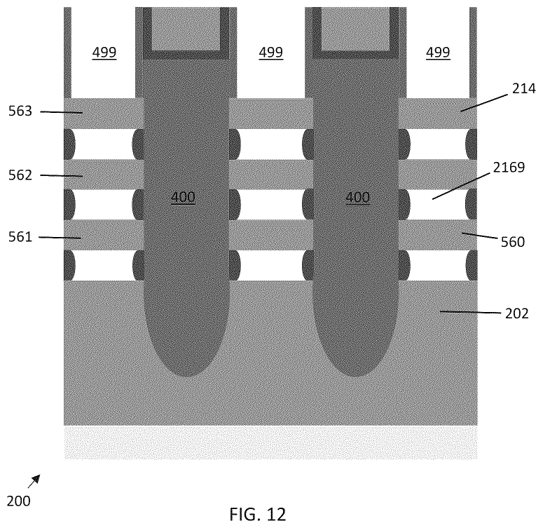

In FIG. 12, method 1000 removes the epitaxial layers 216 of the second composition at operation S1140. As a result, gaps 2169 are formed between the epitaxial layers 214 of the first composition. In this manner, the epitaxial layers 214 of the first composition are formed as vertically-spaced apart semiconductor nanosheets 560. The nanosheets 560 include a lowest nanosheet 561, a highest or uppermost nanosheet 563, and an intermediate nanosheet or nanosheets 562. FIG. 12 is an X-cut cross-sectional view.

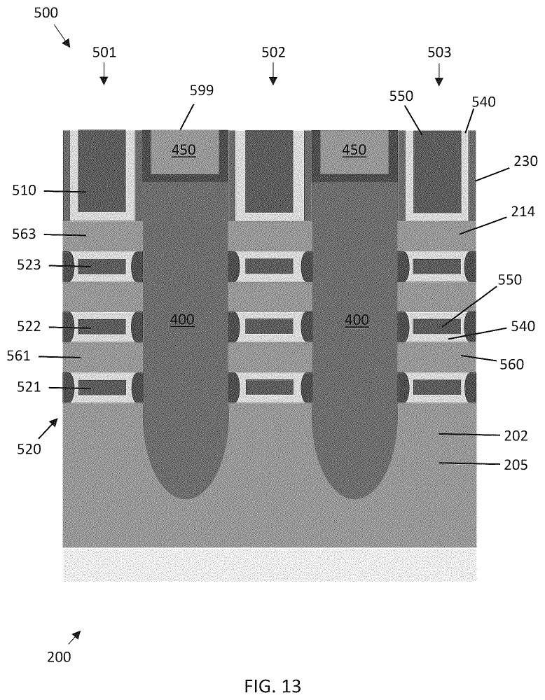

In FIG. 13, method 1000 includes, at operation S1150, completing a replacement metal gate process to form gate structures 500, such as gate structure 501, gate structure 502, and gate structure 503. FIG. 13 is an X-cut cross-sectional view.

In exemplary embodiments, the replacement metal gate process includes forming a gate dielectric layer 540 in the gate cavities 499 and in the gaps 2169, and forming a gate electrode material 550 over the gate dielectric layer 540 to fill the gate cavities 499 and fill the gaps 2169.

An exemplary gate dielectric layer(s) 540 is deposited conformally in the gate cavities 499 and gaps 2169. The gate dielectric 540 may be formed on the semiconductor nanosheets 560, and the gate electrode material 550 may be formed on the gate dielectric layer(s) 540. Thus, each semiconductor nanosheet 560 is wrapped in gate dielectric 540 and surrounded by gate electrode material 550.

In accordance with some embodiments, the gate dielectric layer(s) 540 comprises silicon oxide, silicon nitride, or multilayers thereof. In some embodiments, the gate dielectric layer(s) 540 is a high-k dielectric material, and in these embodiments, the gate dielectric layer(s) 540 may have a k value greater than about 7.0, and may include a metal oxide or a silicate of Hf, Al, Zr, La, Mg, Ba, Ti, Pb, and combinations thereof. The formation methods of the gate dielectric layer(s) 540 may include Molecular-Beam Deposition (MBD), ALD, PECVD, and the like.

The gate electrode material 550 is deposited over the gate dielectric layer(s) 540 and fills the remaining portion of the gate cavity. The gate electrode material 550 may be a metal-containing material such as TiN, TaN, TaC, Co, Ru, Al, combinations thereof, or multi-layers thereof. For example, although a single gate electrode material is illustrated, any number of work function tuning layers may be deposited.

As shown, the FIG. 13, the replacement metal gate process further includes removing excess portions of the gate dielectric layer(s) 540 and the gate electrode material 550 located over the top surface of the ILD 450. For example, a planarization process, such as a CMP process, may be performed to remove the excess portions of the gate dielectric layer(s) 540 and the gate electrode material 550. As a result, the device 200 has an upper surface 599. The remaining portions of material of the gate dielectric layer(s) 540 and the gate electrode material 550 thus form the replacement gate structure 500 of the resulting device 200. The gate dielectric layer(s) 540 and gate electrode material 550 may be collectively referred to as a “gate,” a “gate stack,” or a “gate structure.” Each gate structure 500 may extend along sidewalls of a channel region of the fin structures.

As shown in FIG. 13, each metal gate 500 includes an upper or outer gate portion 510 lying over the uppermost nanosheet 563. Further, each metal gate 500 includes inner gate portions 520 lying under the uppermost nanosheet 563. Specifically, each metal gate 500 includes an uppermost inner gate portion 523 lying directly under the uppermost nanosheet 563, a lowest inner gate portion 521 lying directly under the lowest nanosheet 561, and an intermediate inner gate portion 522 lying directly above the lowest nanosheet 561. Each metal gate 500 lies directly over a central portion 205 of the substrate 202.

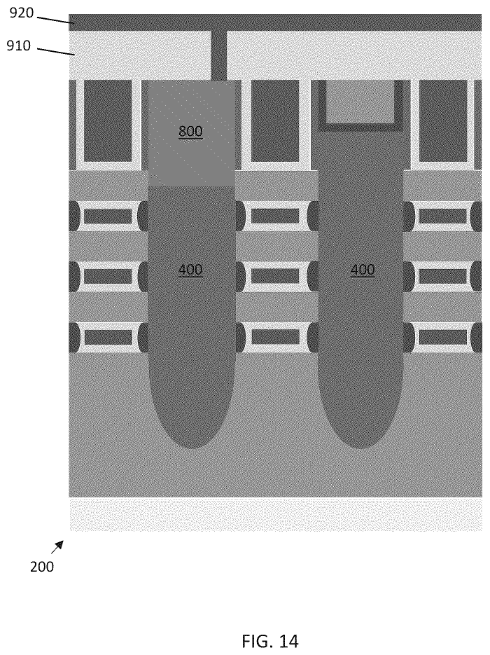

As shown in FIG. 14, method 1000 may continue at operation S1160 with forming an electrical contact 800.

Operation S1160 may include forming dielectric material over the device 200. For example, a layer, such as a contact etch stop layer (CESL) or capping layer, may be formed over the surface 599. In exemplary embodiments, the CESL layer has a vertical thickness, in the Z-direction, of from one to five nanometers.

Further, operation S1160 may include forming a second interlayer dielectric (ILD) layer over the CESL layer. In certain embodiments, the second interlayer dielectric (ILD) layer is silicon oxide or another suitable material. In certain embodiments, the second ILD layer and the first ILD layer 450 are the same material, for example silicon oxide.

Further, operation S1160 may include performing an etch process to form an upper opening over and extending to a selected source/drain feature 400. Also, operation S1160 may include forming silicide on the selected source/drain feature 400.

Then, operation S1160 may include filling the opening over the silicide with a conductive material. In certain embodiments, the conductive material(s) include metal(s), such as tungsten (W) or other suitable materials. A planarization process may be performed to remove an overburden portion of the conductive material from over the dielectric 450. Operation S1160 forms a conductive contact 800, i.e., source/drain contact 800, to selected source/drain feature(s) 400.

Method 1000 may continue at operation S1170 with further processing. For example, dielectric layer(s) 910 and metallization layer(s) 920 may be deposited and etched to form interconnect structures 900 as shown in FIG. 14. The further processing may include other back end of line (BEOL) processes such as passivation and packaging.

FIG. 15 is a flow chart illustrating a sidewall trimming process of operation S1110, in accordance with some embodiments.

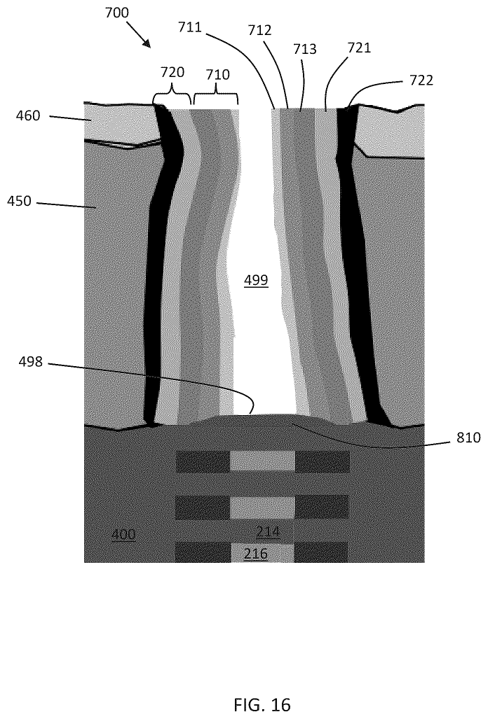

FIGS. 16-23 are cross-sectional views of the semiconductor device during successive stages of fabrication according to the process of FIG. 15, in accordance with some embodiments.

FIG. 16 illustrates an embodiment of the device 100 after operation S1060 opens and removes the sacrificial gate structures 222 to form gate cavity 499. As shown, the cavity 499 extends to a cavity bottom 498 that is defined by an interlayer material 810 that is formed over the fin before the sacrificial gate structure is formed. The interlayer material 810 may be an oxide, such as silicon oxide.

The cavity 499 is bounded at the sides by the sidewall spacer 700 which is formed by more than one layer. As shown, a low-K spacer layer 710 may be the innermost layer. Specifically, the low-K spacer layer 710 may be formed directly on the sacrificial gate structure. In certain embodiments, the low-K spacer layer 710 is formed from low-K material that includes carbon and nitrogen. In certain embodiments, the low-K spacer layer 710 is formed from low-K material that includes silicon, carbon, nitrogen, and/or oxygen. In an embodiment, the low-K spacer layer 710 is formed from SiOCN.

Low-K spacer layer 710 may include a sublayer 711, sublayer 712, and sublayer 713. For example, sublayer 711 may be a soft low-K spacer sublayer 711, sublayer 712 may be a low-K hardshell sublayer 712, and sublayer 713 may be an NFD+KC3P sublayer 713.

As shown, an etch stop layer 720 is formed directly on the low-K spacer layer 710. In certain cases, the etch stop layer 720 or contact etch stop layer (CESL) 720 is formed from a nitride material. For example, the etch stop layer 720 may be formed from silicon nitride. For example, the etch stop layer 720 may be Si₃N₄.

Etch stop layer 720 may include a sublayer 721 and sublayer 722. For example, sublayer 721 may be a low-K CESL sublayer and sublayer 722 may be a silicon nitride CESL sublayer 722.

In FIG. 16, a hard mask 460 is formed over the ILD 450. In certain embodiments, the hard mask 460 is a nitride, such as silicon nitride. For example, the hard mask 460 may be Si₃N₄. In certain embodiments, the ILD 450 is oxide, such as silicon oxide. For example, the ILD 450 may be SiO₂.

Each nanosheet 214 may be a silicon-germanium (SiGe) film.

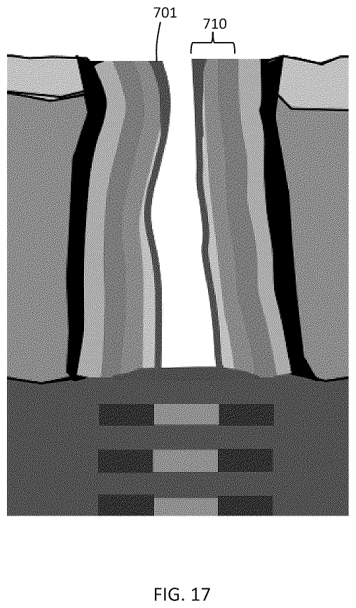

Process S1110 may include at stage S1510, performing a first sidewall spacer treatment as shown in FIG. 17. Specifically, operation S1510 may include causing a chemical reaction in gas, radical, or plasma mode using any gas mixture combination of N₂, H₂, or O₂ under the chamber pressure of from 0.003 to about 3 torr. For example, operation S1510 may be performed at a pressure of at least 1 T, such as at least 1.25 T, at least 1.5 T, at least 1.65 T, at least 1.8 T, or at least 2 T. In certain embodiments, process conditions are flow rates of 3840 sccm N₂+160 sccm H₂+6000 sccm O₂.

In FIG. 17, a first portion 701 of the low-K spacer layer 710 is converted to a more easily removed material. Specifically, the first portion 701 of the low-K spacer layer 710 is oxidized.

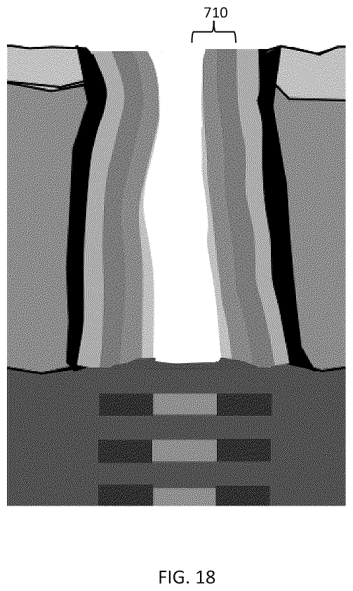

Process S1110 may include at stage S1520, performing a first removal process as shown in FIG. 18. Specifically, operation S1520 may include performing a wet chemical etch using HF solution diluted in DI-water in any suitable ratio. In certain embodiments, the HF:DI-water ratio is 1:500.

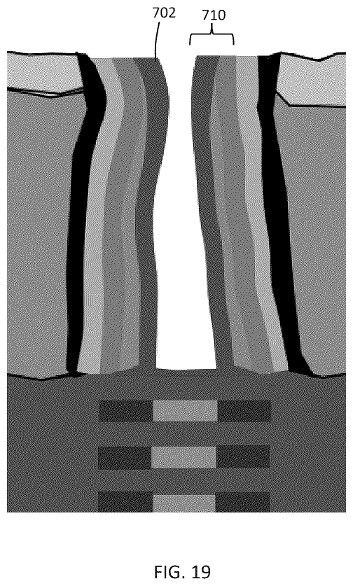

Process S1110 may include at stage S1530, performing a second sidewall spacer treatment as shown in FIG. 19. Specifically, operation S1530 may include causing a chemical reaction in gas, radical, or plasma mode using any gas mixture combination of N₂, H₂, or O₂ under the chamber pressure of from 0.003 to about 3 torr. For example, operation S1530 may be performed at a pressure of at least 1 T, such as at least 1.25 T, at least 1.5 T, at least 1.65 T, at least 1.8 T, or at least 2 T. In certain embodiments, process conditions are flow rates of 3840 sccm N₂+160 sccm H₂+6000 sccm O₂.

In FIG. 19, a second portion 702 of the low-K spacer layer 710 is converted to a more easily removed material. Specifically, the second portion 702 of the low-K spacer layer 710 is oxidized.

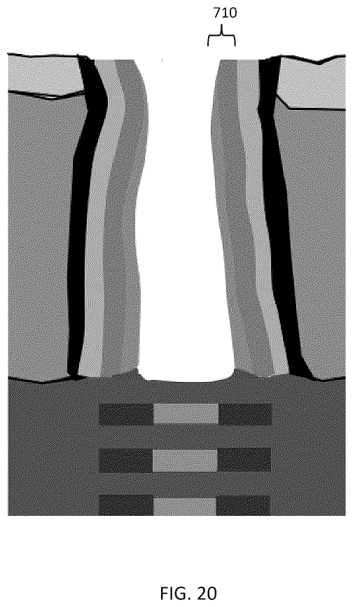

Process S1110 may include at stage S1540, performing a second removal process as shown in FIG. 20. Specifically, operation S1540 may include performing a dry chemical etch using a gas mixture of HF+NH₃ under a chamber pressure of from 0.1 to 1 torr. In certain embodiments, process conditions include use of HF:NH₃ in 1:4 ratio under 0.3 torr. In certain embodiments, the lateral thickness, i.e., in the X-direction, is from 1 to 10 nm, such as from 2 to 8 nm, from 4 to 6 nm, or about 5 nm.

Stage S1540 completes the trimming operation S1110.

FIGS. 20-23 illustrates further operations in accordance with the method 1000 of FIG. 2.

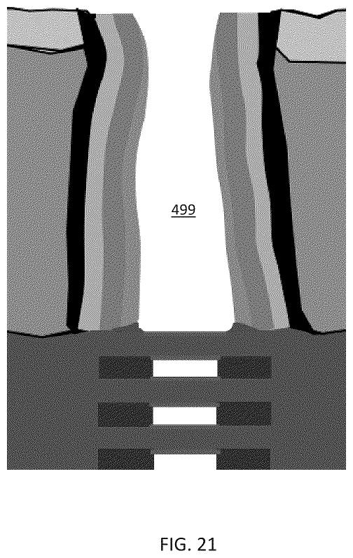

As shown in FIG. 21, method 1000 may include, at operation S1140, removing the epitaxial layers 216.

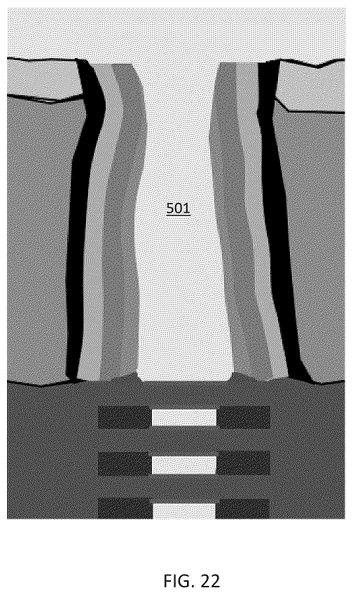

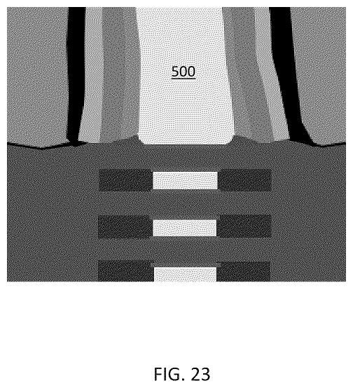

Further, method 1000 may include, at operation S1150, completing replacement gate processing. For example, as shown in FIG. 22, a metal 505 may be deposited in the gate cavity 499. Further, as shown in FIG. 23, the overburden portion of the metal 505 may be removed such as by planarization to form the metal gate 500.

As described above, the method 1000 may continue with forming a contact to selected source/drain features.

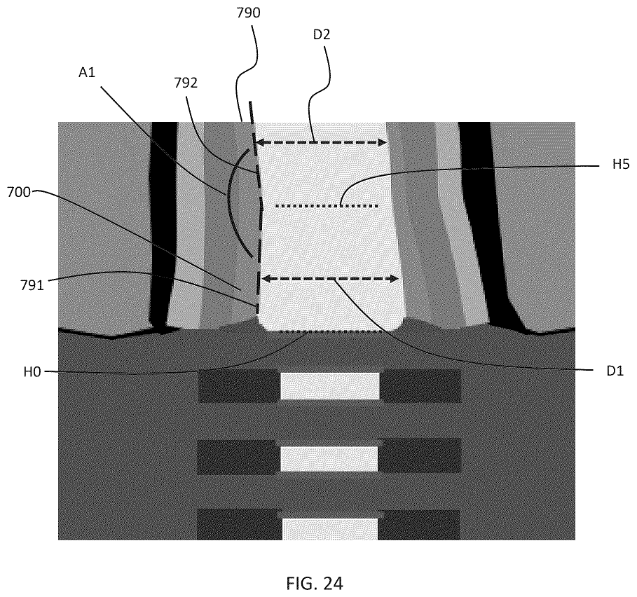

FIG. 24 illustrates certain dimensions of device 100 fabricated according to method 1000. As shown, the cavity or metal gate bottom is at height H0. Height H5 is five nanometers above height H0.

As shown, the sidewall spacer 700 extends from the bottom cavity surface at H0 upward and terminates at a top end 790. FIG. 24 illustrates a vertical profile of the sidewall spacer liner (along an X-cut), which includes a bottom segment 791 extending from the bottom cavity surface H0 to height H5 (5 nanometers above the bottom cavity surface) and a top segment 792 extending from the height H5 to the top end 790 An angle A1 is formed between the bottom segment 791 and the top segment 792 as shown. In certain embodiments, angle A1 is at least 150 degrees. For example angle A1 may be at least 155 degrees, at least 160 degrees, at least 165 degrees, at least 170 degrees, at least 175 degrees, at least 180 degrees, at least 185 degrees, at least 190 degrees, or at least 195 degrees. Further, angle A1 may be at most 200 degrees, at most 195 degrees, at most 190 degrees, at most 185 degrees, at most 180 degrees, at most 175 degrees, at most 170 degrees, at most 165 degrees, at most 160 degrees, at most 155 degrees, or at most 150 degrees.

Further, the X-cut of FIG. 24 illustrates loading of the metal gate profile top-to-bottom critical dimension. For example, a bottom critical dimension D1 (or lateral width along a horizontal plane) is measured at a height between height H0 and height H5. Also a top critical dimension D2 (or lateral width along a horizontal plane) is measured from at a height between height H5 and the top 790. Top 790 may be at a height of 12 nanometers over height H0. Loading is equal to the difference of D2−D1. In certain embodiments, the loading is from 0 to 2.0 nm. For example, the loading may be less than 1.8, less than 1.6, less than 1.4, less than 1.2, less than 1, less than 0.8, less than 0.6, less than 0.5, less than 0.4, less than 0.3, or less than 0.2. Further, loading may be at least 0.1, at least 0.2, at least 0.3, at least 0.4, at least 0.5, at least 0.6, at least 0.7, or at least 0.8.

In certain embodiments, each critical dimensions D1 and D2 is from 14 to 16 nm. For example, critical dimensions D1 and/or D2 may be at least 14.25, at least 14.5, at least 14.75, at least 15, at least 15.25, at least 15.5, at least 15.75, or at least 16 nm. Further, critical dimensions D1 and/or D2 may be at most 16, at least 15.75, at most 15.5, at most 15.25, at most 15, at most 14.75, at most 14.5, or at most 14.25.

In one embodiment, a method includes forming a stack of semiconductor nanosheets over a substrate; forming a sacrificial gate structure over the stack of semiconductor nanosheets; forming a liner adjacent to the sacrificial gate structure; forming a dielectric layer adjacent to the liner; removing the sacrificial gate structure to form a gate cavity; performing an oxidation process to oxidize a portion of the liner adjacent to the gate cavity; and removing the portion of the liner adjacent to the gate cavity.

In certain embodiments of the method, the oxidation process is performed at a pressure of at least 1 Torr.

In certain embodiments of the method, the oxidation process is a second oxidation process and the portion of the liner is a second portion of the liner, and the method further includes performing a first oxidation process at a pressure of at least 1 Torr to oxidize a first portion of the liner adjacent to the gate cavity; and removing the first portion of the liner adjacent to the gate cavity before performing the second oxidation process.

In certain embodiments of the method, removing the first portion of the liner includes performing a wet chemical etch, and removing the second portion of the liner includes performing a dry chemical etch.

In certain embodiments of the method, the liner is a low-K material comprised of silicon, oxygen, carbon, and/or nitrogen.

In certain embodiments, the method further includes forming an interlayer material over the substrate, wherein the sacrificial gate structure and liner are formed over the interlayer material; forming a metal gate structure in the gate cavity; planarizing the metal gate structure and the dielectric layer; forming an isolation layer over the metal gate structure, wherein the liner abuts the isolation layer at a top end and abuts the interlayer material at a bottom end; the liner has a top lateral thickness at the top end and a bottom lateral thickness at the bottom end; and a difference between the top lateral thickness and the bottom lateral thickness is less than 2 nanometers (nm).

In certain embodiments of the method, the difference is less than 1 nm.

In certain embodiments of the method, the liner has a maximum lateral thickness of 16 nm.

In certain embodiments, the method further includes forming a contact etch stop layer on the liner; and forming a hard mask over the dielectric layer adjacent to the contact etch stop layer.

In certain embodiments of the method, the oxidation process is performed at a pressure of at least 1.5 Torr.

In certain embodiments of the method, the oxidation process is performed at a pressure of at least 1.65 Torr.

In another embodiment, a method includes forming a cavity extending to a bottom cavity surface and laterally bounded by a liner; performing a first oxidation process at a pressure of at least 1 Torr to oxidize a first portion of the liner adjacent to the cavity; removing the first portion of the liner; performing a second oxidation process to oxidize a second portion of the liner adjacent to the cavity; and removing the second portion of the liner.

In certain embodiments of the method, the second oxidation process is performed at a pressure of at least 1 Torr.

In certain embodiments of the method, after removing the second portion of the liner, a remaining portion of the liner extends upward from the bottom cavity surface and terminates at a top end, and wherein the remaining portion of the liner has a critical dimension differential from the bottom cavity surface to the top end, and wherein the thickness differential is less than 2 nanometers (nm).

In certain embodiments of the method, the critical dimension differential is less than 1 nanometer (nm).

In certain embodiments of the method, the remaining portion of the liner has a maximum lateral critical dimension of 16 nm.

In certain embodiments of the method, after removing the second portion of the liner, a remaining portion of the liner extends upward from the bottom cavity surface and terminates at a top end; a vertical profile of the remaining portion of the liner includes a bottom segment extending from the bottom cavity surface to a height of 5 nanometers above the bottom cavity surface; the vertical profile of the remaining portion of the liner includes a top segment extending from the height of 5 nanometers above the bottom cavity surface to the top end; an angle is formed between the bottom segment and the top segment; and the angle is at least 150 degrees.

In certain embodiments of the method, the angle is from 160 degrees to 200 degrees.

In another embodiment, a semiconductor structure includes a metal gate lying over a stack of nanosheet channels and having a sidewall extending from a bottom end to a top end; and a low-K liner including of silicon, oxygen, carbon, and/or nitrogen surrounding the sidewall of the metal gate, wherein a vertical profile of the low-K liner includes a bottom segment extending from the bottom end of the metal gate to a height above the bottom end of the metal gate, the vertical profile of the low-K liner includes a top segment extending from the height above the metal gate to the top end of the metal gate, an angle is formed between the bottom segment and the top segment, and the angle is at least 150 degrees.

In certain embodiments of the structure, the height is 5 nanometers above the bottom end of the metal gate.

In certain embodiments of the structure, the metal gate has a thickness differential from the bottom end to the top end, and the thickness differential is less than 2 nanometers (nm).

In certain embodiments of the structure, the thickness differential is less than 1 nanometer (nm).

In certain embodiments of the structure, the metal gate has a maximum lateral thickness of 16 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of semiconductor nanosheets over a substrate;
forming a sacrificial gate structure over the stack of semiconductor nanosheets;
forming a liner adjacent to the sacrificial gate structure;
forming a dielectric layer adjacent to the liner;
removing the sacrificial gate structure to form a gate cavity;
performing an oxidation process to oxidize a portion of the liner adjacent to the gate cavity; and
removing the portion of the liner adjacent to the gate cavity.

2. The method of claim 1, wherein the oxidation process is performed at a pressure of at least 1 Torr.

3. The method of claim 1, wherein the oxidation process is a second oxidation process and the portion of the liner is a second portion of the liner, and wherein the method further comprises:
performing a first oxidation process at a pressure of at least 1 Torr to oxidize a first portion of the liner adjacent to the gate cavity; and
removing the first portion of the liner adjacent to the gate cavity before performing the second oxidation process.

4. The method of claim 3, wherein:
removing the first portion of the liner comprises performing a wet chemical etch; and
removing the second portion of the liner comprises performing a dry chemical etch.

5. The method of claim 1, wherein the liner is a low-K material comprised of silicon, oxygen, carbon, and/or nitrogen.

6. The method of claim 1, further comprising:
forming an interlayer material over the substrate, wherein the sacrificial gate structure and liner are formed over the interlayer material;
forming a metal gate structure in the gate cavity;
planarizing the metal gate structure and the dielectric layer;
forming an isolation layer over the metal gate structure,
wherein the metal gate structure abuts the isolation layer at a top end and abuts the interlayer material at a bottom end; wherein the metal gate structure has a top lateral thickness at the top end and a bottom lateral thickness at the bottom end; and wherein a difference between the top lateral thickness and the bottom lateral thickness is less than 2 nanometers (nm).

7. The method of claim 6, wherein the difference is less than 1 nm.

8. The method of claim 6, wherein the metal gate structure has a maximum lateral thickness of 16 nm.

9. The method of claim 1, further comprising:
forming a contact etch stop layer on the liner; and
forming a hard mask over the dielectric layer adjacent to the contact etch stop layer.

10. The method of claim 1, wherein the oxidation process is performed at a pressure of at least 1.5 Torr.

11. The method of claim 1, wherein the oxidation process is performed at a pressure of at least 1.65 Torr.

12. A method comprising:
forming a cavity extending to a bottom cavity surface and laterally bounded by a liner;
performing a first oxidation process at a pressure of at least 1 Torr to oxidize a first portion of the liner adjacent to the cavity;
removing the first portion of the liner;
performing a second oxidation process to oxidize a second portion of the liner adjacent to the cavity; and
removing the second portion of the liner.

13. The method of claim 12, wherein the second oxidation process is performed at a pressure of at least 1 Torr.

14. The method of claim 12, wherein after removing the second portion of the liner, a remaining portion of the liner extends upward from the bottom cavity surface and terminates at a top end, and wherein the remaining portion of the liner has a critical dimension differential from the bottom cavity surface to the top end, and wherein the critical dimension differential is less than 2 nanometers (nm).

15. The method of claim 14, wherein the critical dimension differential is less than 1 nanometer (nm) and wherein the remaining portion of the liner has a maximum lateral critical dimension of 16 nm.

16. The method of claim 12, wherein:
after removing the second portion of the liner, a remaining portion of the liner extends upward from the bottom cavity surface and terminates at a top end;
a vertical profile of the remaining portion of the liner includes a bottom segment extending from the bottom cavity surface to a height of 5 nanometers above the bottom cavity surface;
the vertical profile of the remaining portion of the liner includes a top segment extending from the height of 5 nanometers above the bottom cavity surface to the top end;
an angle is formed between the bottom segment and the top segment; and
the angle is at least 150 degrees.

17. A semiconductor structure comprising:
a metal gate lying over a stack of nanosheet channels and having a sidewall extending from a bottom end to a top end;
a low-K liner comprised of silicon, oxygen, carbon, and/or nitrogen surrounding the sidewall of the metal gate, wherein a vertical profile of the low-K liner includes a bottom segment extending from the bottom end of the metal gate to a height above the bottom end of the metal gate, wherein the vertical profile of the low-K liner includes a top segment extending from the height above the metal gate to the top end of the metal gate, wherein an angle is formed between the bottom segment and the top segment, and wherein the angle is at least 150 degrees.

18. The semiconductor structure of claim 17, wherein the height is 5 nanometers above the bottom end of the metal gate.

19. The semiconductor structure of claim 17, wherein the metal gate has a thickness differential from the bottom of the metal gate to the top end, and wherein the thickness differential is less than 2 nanometers (nm).

20. The semiconductor structure of claim 19, wherein the thickness differential is less than 1 nanometer (nm) and wherein the metal gate has a maximum lateral thickness of 16 nm.
